(19) United States
(12) Patent Application Publication
(10) Pub. No.: US 2026/0191100 A1
(43) Pub. Date: Jul. 2, 2026

(54) SEMICONDUCTOR PACKAGE AND METHOD OF MANUFACTURING SEMICONDUCTOR PACKAGE

(71) Applicant: Samsung Electronics Co., Ltd., Suwon-si (KR)

(72) Inventors: Yonghyun Kim, Suwon-si (KR); Wonil Seo, Suwon-si (KR); Sanghyeon Lee, Suwon-si (KR); Taejun Jeon, Suwon-si (KR)

(21) Appl. No.: 19/235,024

(22) Filed: Jun. 11, 2025

(30) Foreign Application Priority Data
Dec. 26, 2024 (KR) 10-2024-0197233

(51) Int. Cl. H01L 23/00; H01L 23/31; H01L 23/498; H01L 25/00; H01L 25/065

(52) U.S. Cl. CPC H10W 90/00; H10W 70/60; H10W 70/6528; H10W 72/834; H10W 72/874; H10W 72/9415; H10W 74/117; H10W 90/20; H10W 90/22; H10W 90/26; H10W 90/701; H10W 90/732; H10W 90/734

(57) ABSTRACT

A semiconductor package includes a substrate including bonding pads, first semiconductor chips stacked on the substrate, first connection members disposed on the substrate and the first semiconductor chips, each first connection member electrically connecting a corresponding first bonding pad to each first semiconductor chip, and connection bumps disposed below the substrate and electrically connected to the bonding pads. Each first semiconductor chip includes first connection pads adjacent to a first edge of the first front surface, a passivation layer disposed on the first front surface, and first trenches disposed in the passivation layer and extending from the first edge of the first front surface toward the first connection pads. Each first trench exposes at least a portion of a corresponding first connection pad.

### CROSS-REFERENCE TO RELATED APPLICATION(S)

This application claims benefit of priority to Korean Patent Application No. 10-2024-0197233 filed on Dec. 26, 2024 in the Korean Intellectual Property Office, the disclosure of which is herein incorporated by reference in its entirety.

### BACKGROUND

The present inventive concept relates to a semiconductor package and a method of manufacturing the same.

With the advancement of the electronics industry, demand for implementation of high performance and miniaturization of electronic components has been increasing. A semiconductor package including a plurality of wire-bonded semiconductor chips has limitations in implementing a fine pitch of a connection pad and reducing a thickness of a semiconductor package due to a shape of a bonding wire, for example, a ball size, a height of a wire loop, or the like.

### SUMMARY

An aspect of the present inventive concept provides a semiconductor package having a reduced size and high performance, and a method of manufacturing the same.

According to an aspect of the present disclosure, a semiconductor package includes a substrate including a plurality of bonding pads, a plurality of first semiconductor chips stacked on the substrate in a vertical direction perpendicular to an upper surface of the substrate, wherein each first semiconductor chip of the plurality of first semiconductor chips has a first rear surface facing the substrate, a first front surface opposite to the first rear surface, and a plurality of side surfaces connecting the first front surface to the first rear surface, a plurality of first connection members disposed on the substrate and the plurality of first semiconductor chips, wherein each first connection member of the plurality of first connection members electrically connects a corresponding first bonding pad of the plurality of bonding pads to each first semiconductor chip of the plurality of first semiconductor chips, and a plurality of connection bumps disposed below the substrate and electrically connected to the plurality of bonding pads. Each first semiconductor chip of the plurality of first semiconductor chips includes a plurality of first connection pads adjacent to a first edge of the first front surface, a passivation layer disposed on the first front surface, and a plurality of first trenches disposed in the passivation layer and extending from the first edge of the first front surface toward the plurality of first connection pads. Each first trench of the plurality of first trenches exposes at least a portion of a corresponding first connection pad of the plurality of first connection pads. Each first connection member of the plurality of first connection members includes a first bonding pattern extending from a corresponding bonding pad of the plurality of bonding pads toward a lowermost first semiconductor chip among the plurality of first semiconductor chips in a horizontal direction parallel to the upper surface of the substrate, a first conductive pattern having a first end connected to the first bonding pattern and a second end disposed in a corresponding first trench of the plurality of first trenches, and a plurality of first insulating patterns separated from each other in the vertical direction. Each first insulating pattern of the plurality of first insulating patterns is disposed in a space between the first conductive pattern and a first side surface of the plurality of side surfaces of a corresponding first semiconductor chip of the plurality of first semiconductor chips. The first side surface is connected to the first edge of the first front surface.

According to an aspect of the present disclosure, a semiconductor package includes a substrate including a plurality of bonding pads, a plurality of semiconductor chips stacked on the substrate in a vertical direction perpendicular to an upper surface of the substrate, each semiconductor chip of the plurality of semiconductor chips having a rear surface facing the substrate, a front surface opposite to the rear surface, and a plurality of side surfaces connecting the front surface to the rear surface, a plurality of attachment films, each attachment film being disposed on a rear surface of a corresponding semiconductor chip of the plurality of semiconductor chips, and a plurality of connection members electrically connecting the plurality of semiconductor chips and the plurality of bonding pads of the substrate with each other. Each of the plurality of semiconductor chips includes a plurality of connection pads adjacent to a first edge of the front surface, and a passivation layer disposed on the front surface, the passivation layer exposing at least a portion of each connection pad of the plurality of connection pads. Each connection member of at least some connection members, among the plurality of connection members, includes a plurality of insulating patterns on one side surface, among the plurality of side surfaces of each of the plurality of semiconductor chips, that is connected to the first edge, and a plurality of conductive patterns extending from the plurality of connection pads of each semiconductor chip of the plurality of semiconductor chips onto the plurality of insulating patterns, the plurality of conductive patterns electrically connected to the plurality of bonding pads.

According to an aspect of the present disclosure, a semiconductor package includes a substrate including a plurality of bonding pads, a plurality of semiconductor chips stacked on the substrate in a vertical direction perpendicular to an upper surface of the substrate, each semiconductor chip of the plurality of semiconductor chips having a rear surface facing the substrate, a front surface opposite to the rear surface, and a plurality of side surfaces connecting the front surface to the rear surface, and a plurality of connection members electrically connecting the plurality of semiconductor chips and the plurality of bonding pads of the substrate with each other. Each semiconductor chip of the plurality of semiconductor chips includes a plurality of connection pads adjacent to a first edge of the front surface, a passivation layer disposed on the front surface, the passivation layer exposing at least a portion of each connection pad of the plurality of connection pads, and a conductive dummy pattern exposed at the front surface and a first side surface among the plurality of side surfaces, the first side surface being connected to the first edge of the front surface. The plurality of connection members include a first group of connection members, each connection member of the first group of connection members including a plurality of insulating patterns, each insulating pattern covering a conductive dummy pattern exposed at a first side surface of the plurality of side surfaces and a front surface of a corresponding semiconductor chip of the plurality of semiconductor chips, and a plurality of conductive patterns extending from the plurality of connection pads of each semiconductor chip of the plurality of semiconductor chips onto the plurality of insulating patterns, the plurality of conductive patterns electrically connected to the plurality of bonding pads.

According to another aspect of the present inventive concept, there is provided a method of manufacturing a semiconductor package, the method including preparing a semiconductor wafer including a preliminary passivation layer covering chip regions, attaching a preliminary attachment film to a rear surface of the semiconductor wafer, cutting the semiconductor wafer to form a plurality of semiconductor chips, the plurality of semiconductor chips respectively corresponding to the chip regions, the plurality of semiconductor chips having a front surface on which a passivation layer formed by cutting the preliminary passivation layer is disposed, and a rear surface on which an attachment film formed by cutting the preliminary attachment film is disposed, forming insulating patterns covering one side surface of each of the plurality of semiconductor chips, forming conductive patterns extending from connection pads of each of the plurality of semiconductor chips onto the insulating patterns, forming bonding patterns on a substrate including bonding pads, the bonding patterns extending in at least one direction from the bonding pads, attaching the plurality of semiconductor chips to the substrate, the plurality of semiconductor chips being stacked such that an end of each of the conductive patterns is electrically connected to one of the conductive patterns, adjacent to each other in a vertical direction, and the bonding patterns, curing the bonding patterns and the conductive patterns, forming a molding layer covering the plurality of semiconductor chips, and forming connection bumps electrically connected to the bonding pads.

The method of manufacturing a semiconductor package, further comprises forming trenches by removing at least a portion of the preliminary passivation layer before or after attaching the preliminary attachment film.

In the method of manufacturing a semiconductor package, the trenches expose the connection pads on the front surface, and extend to at least one edge of the chip regions, and the conductive patterns extend along the trenches.

The method of manufacturing a semiconductor package, further comprises forming connection patterns between the end of each of the conductive patterns and one of the conductive patterns and between the bonding patterns, before the curing.

The method of manufacturing a semiconductor package, wherein the insulating patterns, the conductive patterns, and the bonding patterns are formed through a dispensing process or a printing process.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a perspective view of a semiconductor package according to an example embodiment, FIG. 1B is a partially enlarged view of FIG. 1A, and FIG. 1C is a cross-sectional view taken along line I-I′ of FIG. 1B;

FIG. 2 is a partially enlarged view of a semiconductor package according to an example embodiment;

FIGS. 3A, 3B, 3C, 3D, 3E, 3F and 3G are diagrams illustrating a process of manufacturing the semiconductor package of FIG. 1A;

FIG. 4 is a partially enlarged view of a semiconductor package according to an example embodiment;

FIG. 5A is a perspective view of a semiconductor package according to an example embodiment, and FIG. 5B is a cross-sectional view taken along line II-II′ of FIG. 5A;

FIG. 6A is a perspective view of a semiconductor package according to an example embodiment, and FIG. 6B is a cross-sectional view taken along line III-III′of FIG. 6A;

FIG. 7 is a partially enlarged view of a semiconductor package according to an example embodiment;

FIG. 8 is a partially enlarged view of a semiconductor package according to an example embodiment;

FIG. 9A is a partially enlarged view of a semiconductor package according to an example embodiment, and FIG. 9B is a cross-sectional view taken along line IV-IV′ of FIG. 9A;

FIGS. 10A and 10B are diagrams illustrating a process of manufacturing the semiconductor package of FIG. 9A;

FIG. 11A is a partially enlarged view of a semiconductor package according to an example embodiment, and FIG. 11B is a cross-sectional view taken along line V-V′ of FIG. 11A; and

FIGS. 12A and 12B are diagrams illustrating a manufacturing process of the semiconductor package of FIG. 11A.

### DETAILED DESCRIPTION

Hereinafter, preferred example embodiments will be described in detail. Unless otherwise described, the terms such as “upper,” “upper portion,” “upper surface,” “lower,” “lower portion,” “lower surface,” and “side surface” are based on the drawings, and may vary depending on a direction in which a component is actually arranged.

In addition, ordinal numbers such as “first,” “second,” “third,” and the like may be used as labels for specific elements, operations, directions, and the like, to distinguish various elements, steps, directions, and the like from one another. A term, not described in the specification using “first,” “second,” and the like, may still be referred to as “first” or “second” in the claims. In addition, a term referenced by a particular ordinal number (for example, “first” in a particular claim) may be described elsewhere with a different ordinal number (for example, “second” in the specification or another claim).

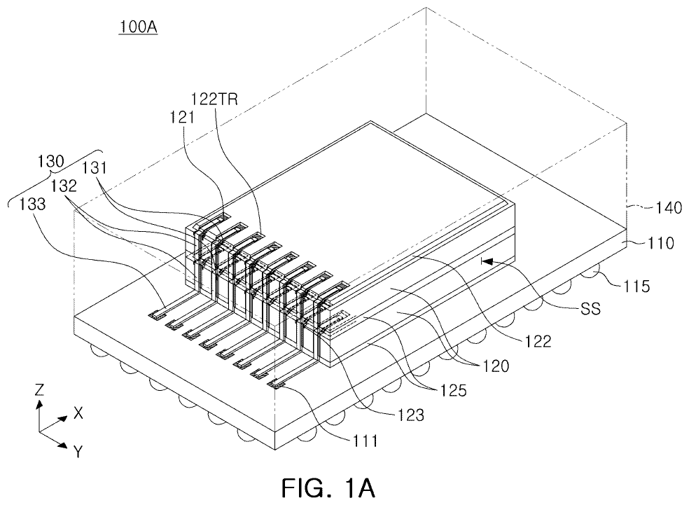

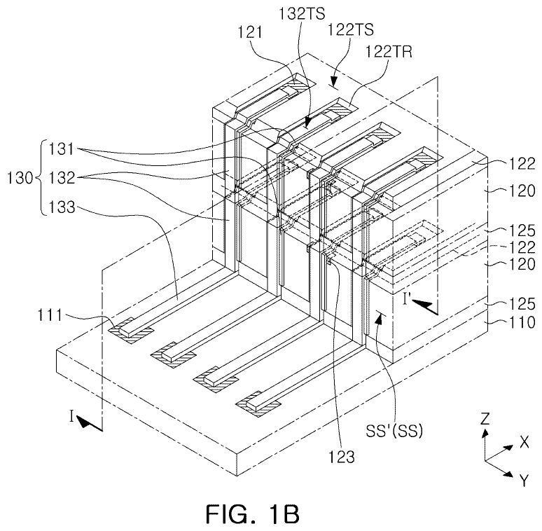

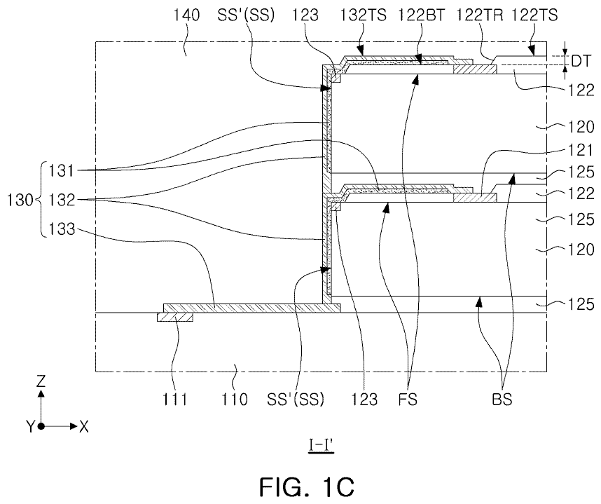

FIG. 1A is a perspective view of a semiconductor package according to an example embodiment, FIG. 1B is a partially enlarged view of FIG. 1A, and FIG. 1C is a cross-sectional view taken along line I-I′ of FIG. 1B.

Referring to FIGS. 1A to 1C, a Semiconductor Package 100A According to an example embodiment may include a substrate 110, a plurality of semiconductor chips 120, a plurality of connection members 130, and a molding layer 140. According to example embodiments, the plurality of connection members 130 may contact side surfaces SS of the plurality of semiconductor chips 120 to connect connection pads 121 and bonding pad 111 to each other, thereby miniaturizing an electrical connection path and a connection pad without a structural restriction of a bonding wire, for example, a restriction of a ball size of a wire, or a height of a wire loop, and reducing a thickness of a semiconductor package. In addition, insulating patterns 131 may be disposed in spaces between the side surfaces SS of the semiconductor chips 120 and conductive patterns 132, thereby further improving connection reliability between semiconductor chips 120.

The substrate 110 may be a substrate for a semiconductor package. The substrate 110 may include a printed circuit board (PCB), a ceramic substrate, a glass substrate, or a tape interconnection substrate. For example, the substrate 110 may be a double-sided PCB or a multilayer PCB.

The substrate 110 may include bonding pads 111. The bonding pads 111 may be disposed on an upper surface of the substrate 110, and may include at least one metal or an alloy including two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C). the Bonding pads 111 may be electrically connected to connection bumps 115 disposed below the substrate 110. The connection bumps 115 may include, for example, tin (Sn) or an alloy including tin (Sn). The substrate 110 may include lower pads on which the connection bumps 115 are disposed, and an internal circuit connecting the lower pads to the bonding pads 111. The connection bumps 115 may be electrically connected to an external device such as a module substrate and a system board.

The plurality of semiconductor chips 120 may have a rear surface BS facing the substrate 110, a front surface FS on which the connection pads 121 are arranged, and side surfaces SS intersecting the rear surface BS and the front surface FS. For example, the side surfaces SS may connect the front surface FS to the rear surface BS. The plurality of semiconductor chips 120 may include the connection pads 121 disposed on the front surface FS. The connection pads 121 may be electrically connected to the plurality of connection members 130. The connection pads 121 may include one of copper (Cu), nickel (Ni), titanium (Ti), and aluminum (Al), and an alloy thereof. The connection pads 121 may be arranged to be adjacent to at least one edge of the semiconductor chip 120. For example, the connection pads 121 may be arranged in four columns to be respectively adjacent to four edges of the semiconductor chip 120.

The plurality of semiconductor chips 120 may include a passivation layer 122 disposed on the front surface FS. The passivation layer 122 may expose at least a portion of each of the connection pads 121. The passivation layer 122 may include a single-layer insulating film or multilayer insulating film. For example, the passivation layer 122 may include an oxide film and/or a nitride film. In some example embodiments, the passivation layer 122 may include photosensitive polyimide (PSPI). The passivation layer 122 may have trenches 122TR extending to one side surface SS′ adjacent to the connection pads 121. A portion of each of the plurality of connection members 130 may be disposed in one of the trenches 122TR. The trenches 122TR may surround a portion of the conductive patterns 132 being pressed in a process of stacking the semiconductor chips 120, and a portion of the front surface FS of the semiconductor chip 120. The trenches 122TR may prevent a short circuit between the conductive patterns 132 in a horizontal direction (for example, a Y-direction). The trenches 122TR may be filled by one of the attachment films 125 adjacent to each other in a vertical direction (Z-direction). In an embodiment, the trenches 122TR may be disposed in the passivation layer 122. Each trench of the trenches 122TR may expose a portion of a corresponding connection pads 121. Each trench may extend from the one side surface SS′ toward the corresponding connection pad of the connection pads 121.

The plurality of semiconductor chips 120 may include a conductive dummy pattern 123 exposed to a surface (for example, one side surface SS′ and the front surface FS) adjacent to the connection pads 121, among the side surfaces SS. The conductive dummy pattern 123 may be a residual portion of a pattern disposed in a scribe region of a semiconductor wafer. For example, the conductive dummy pattern 123 may be a portion of a test element group (TEG) pattern.

The plurality of semiconductor chips 120 may be attached to or mutually attached to the substrate 110 by the attachment film 125. The attachment film 125 may be disposed on the rear surface BS of each of the plurality of semiconductor chips 120. The attachment film 125 may be formed using an adhesive film or an adhesive paste. The attachment film 125 may be a die attach film (DAF), but the present inventive concept is not limited thereto.

The plurality of semiconductor chips 120 may be stacked on the substrate 110 in the vertical direction (Z-direction). The plurality of semiconductor chips 120 may be stacked such that the side surfaces SS are aligned in the vertical direction (Z-direction). For example, the connection pads 121 may overlap the semiconductor chips 120 adjacent to each other in the vertical direction (Z-direction). In FIGS. 1A to 1C, two semiconductor chips 120 may be stacked. The present disclosure is not limited thereto. In an embodiment, a number of the plurality of semiconductor chips 120 that are stacked may be greater than 2.

The plurality of semiconductor chips 120 may include a non-volatile memory chip such as a flash memory, a phase-change random access memory (PRAM), a magneto-resistive random access memory (MRAM), a ferroelectric random access memory (FeRAM), and a resistive random access memory (RRAM), or a volatile memory chip such as a dynamic random access memory (DRAM) and a static random access memory (SRAM). The plurality of semiconductor chips 120 may include the same type of semiconductor chips, but the present inventive concept is not limited thereto. In some example embodiments, the plurality of semiconductor chips 120 may include different types of semiconductor chips.

The plurality of connection members 130 may electrically connect the plurality of semiconductor chips 120 and the bonding pads 111 of the substrate 110 with each other. The plurality of connection members 130 may include insulating patterns 131, conductive patterns 132, and bonding patterns 133.

The insulating patterns 131 may be disposed on at least one side surface SS′ of each of the plurality of semiconductor chips 120 adjacent to the connection pads 121. Each of the insulating patterns 131 may be disposed in a space between a corresponding conductive pattern of the conductive patterns 132 and a one side surface SS′ of a corresponding semiconductor chip of the plurality of semiconductor chips 120. The insulating patterns 131 may be separated from each other in a vertical direction (Z-direction), perpendicular to the front surface FS. In some embodiments, each of the insulating patterns 131 may extend to a space between a bottom 122BT of a corresponding trench of the trenches 122TR and a corresponding conductive pattern of the conductive patterns 132. In an embodiment, each of the conductive patterns 132 may include a vertical portion and a horizontal portion. Each insulating pattern 131 may be disposed in a space between the vertical portion and the one side surface SS′ and may be further disposed between the horizontal portion and the bottom 122BT.

The conductive patterns 132 may electrically connect the connection pads 121 and the bonding pads 111 to each other. The conductive patterns 132 may extend from the connection pads 121 of each of the plurality of semiconductor chips 120 to an inside of the trenches 122TR and onto the insulating patterns 131. The conductive patterns 132 may be electrically isolated from the conductive dummy pattern 123 by the insulating patterns 131.

The bonding patterns 133 may electrically connect the conductive patterns 132 and the bonding pads 111 to each other. The bonding patterns 133 may extend from the bonding pads 111 to a lowermost conductive pattern 132, among the conductive patterns 132. At least a portion of the bonding patterns 133 may be buried in the attachment film 125. In some embodiments, the connection members 130 may extend in a first horizontal direction (X-direction) and may be spaced apart from each other in a second horizontal direction (Y-direction). The first and second horizontal directions may be parallel to the front surface FS. Each of the connection members 130 may connect a corresponding bonding pad 111 to each of the plurality of semiconductor chips 120. Each connection member 130 may include insulating patterns 131, a conductive pattern 132, and a bonding pattern 133. In each connection member 130, the bonding pattern 133 may be connected to the corresponding bonding pad 111 and extend toward a lowermost semiconductor chip 120 in the first horizontal direction (X-direction). The conductive pattern 132 may include a vertical portion and horizontal portions. The vertical portion may extend along a one side surface SS′ of each semiconductor chip 120 in the vertical direction. The vertical portion may include vertical sections that are connected in the vertical direction. Each vertical section may be adjacent to one side surface SS′ of a corresponding semiconductor chip 120. Each of the horizontal portions may be connected to an upper end of a corresponding vertical section and extend in the first horizontal direction (X-direction). A number of the horizontal portions may be equal to a number of the semiconductor chips that are stacked in the vertical direction. Each horizontal portion may be disposed in a corresponding trench 122TR to be connected to a bonding pad 111 of a corresponding semiconductor chip.

The trenches 122TR may be formed to have a depth DT greater than a thickness of each of the conductive patterns 132 in the vertical direction (Z-direction), perpendicular to the front surface FS. In an embodiment, in each trench, the depth DT may be greater than a thickness, in the vertical direction, of a horizontal portion of a corresponding conductive pattern. The passivation layer 122 may have an upper end surface 122TS having a step with respect to the bottom 122BT of each of the trenches 122TR. The upper end surface 122TS (i.e., the upper surface) of the passivation layer 122 may be on a level the same as or higher than an upper end surface 132TS of each of the conductive patterns 132 on the bottom 122BT of each of the trenches 122TR. The conductive patterns 132 in the trenches 122TR may overlap the passivation layer 122 in the second horizontal direction (for example, the Y-direction), parallel to the front surface FS. In an embodiment, each of the trenches 122TR may partially extend from the upper surface 122TS of a corresponding passivation layer 122 toward the front surface FS of a corresponding semiconductor chip 120 in the vertical direction so that the bottom 122BT corresponds to an upper surface of the partially removed portion of the passivation layer 122.

An end of each of the conductive patterns 132, positioned on one side surface SS′ of a corresponding semiconductor chip 120, may be electrically connected to one of the conductive patterns 132 or the bonding pattern 133, adjacent to each other in the vertical direction (Z-direction). The end of each of the conductive patterns 132 may contact one of the conductive patterns 132 or the bonding pattern 133, adjacent to each other in the vertical direction (Z-direction). In some example embodiments, the conductive patterns 132 may not be clearly distinguished from each other, and the conductive pattern 132 and the bonding pattern 133 may not be clearly distinguished from each other.

The molding layer 140 may cover the plurality of semiconductor chips 120, on the substrate 110. The molding layer 140 may include a thermosetting resin such as an epoxy resin, a thermoplastic resin such as polyimide, or a resin in which the thermosetting resin or the thermoplastic resin is impregnated with an inorganic filler, for example, a prepreg which refers to a pre-impregnated composite material, an Ajinomoto build-up film (ABF), flame retardant (FR)-4, bismaleimide triazine (BT), or an epoxy molding compound (EMC). The molding layer 140 may cover an uppermost conductive pattern 132, among the conductive patterns 132.

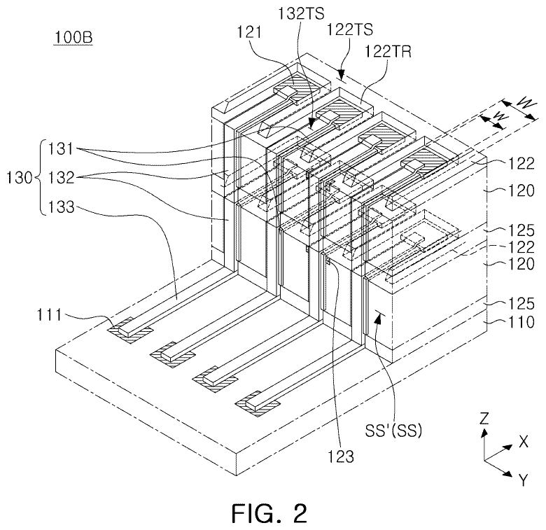

FIG. 2 is a partially enlarged view of a semiconductor package 100B according to an example embodiment.

Referring to FIG. 2, the semiconductor package 100B according to an example embodiment may have features the same as or similar to those described with reference to FIGS. 1A to 1C, except that a width of each of the trenches 122TR is changed. The trenches 122TR may expose the entire corresponding connection pads 121. The trenches 122TR may have a width W greater than a width w of each of the connection pads 121 in a horizontal direction (for example, a Y-direction). The trenches 122TR may prevent the spread of conductive ink, thereby preventing a short circuit between adjacent conductive patterns 132. In addition, according to the example embodiment, a sufficiently wide space between inner walls of the trenches 122TR and the conductive patterns 132 may be secured, thereby improving filling properties of the attachment film 125 in a process of stacking the semiconductor chips 120 and preventing defects such as occurrence of voids.

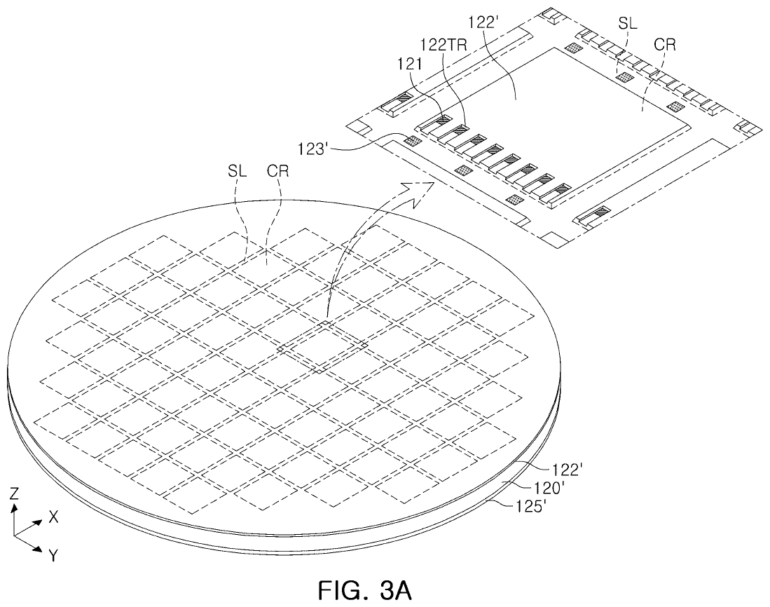

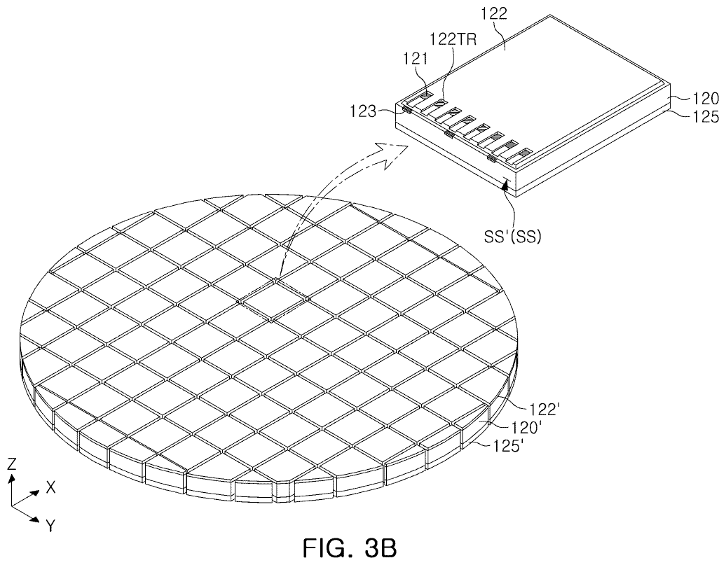

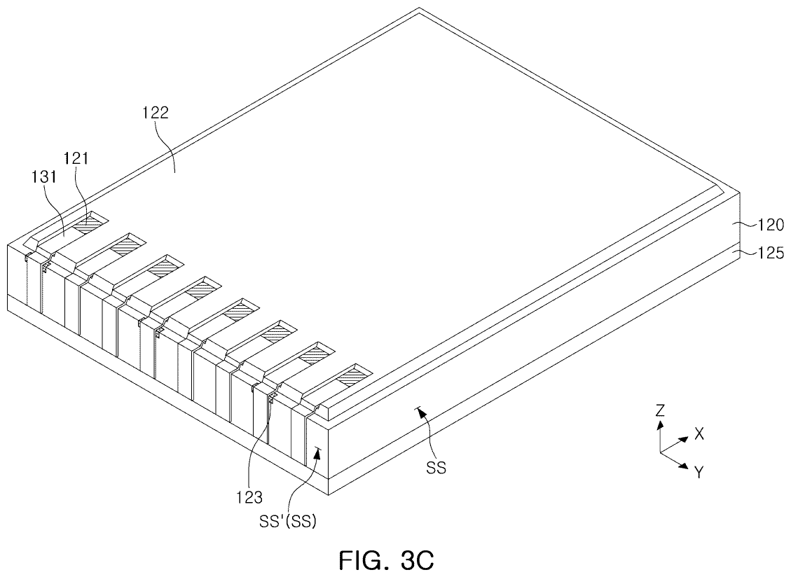

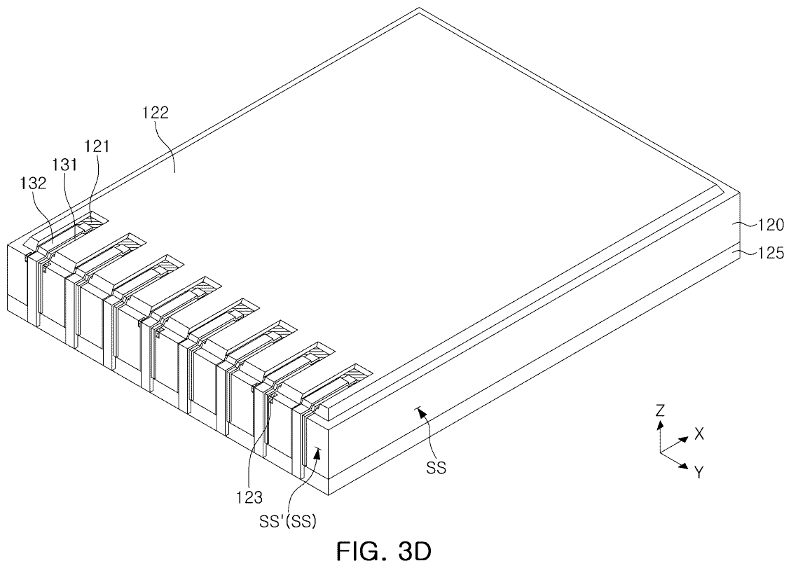

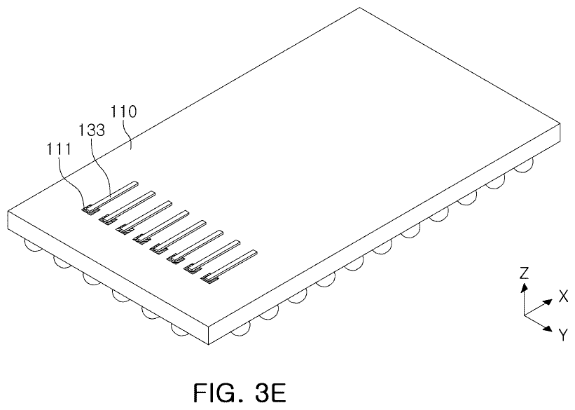

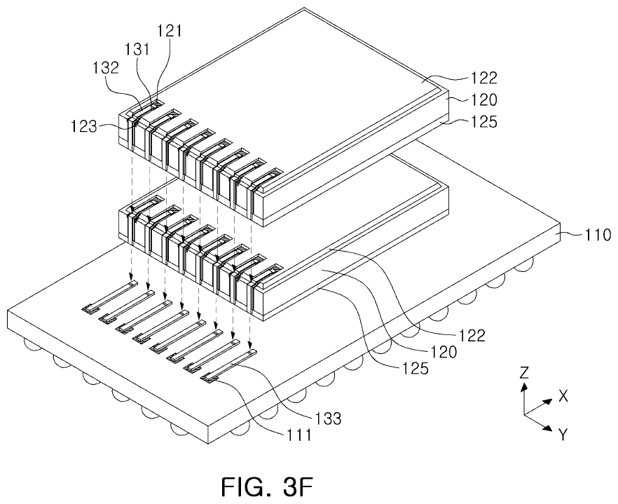

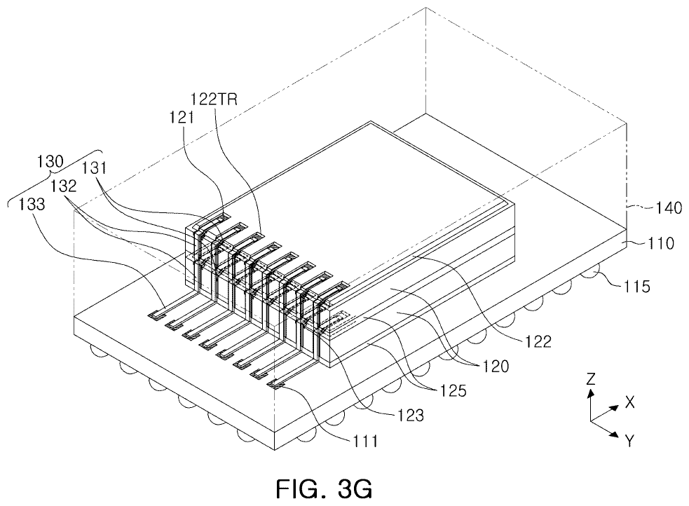

FIGS. 3A to 3G are diagrams illustrating a process of manufacturing the semiconductor package of FIG. 1A.

Referring to FIG. 3A, a preliminary attachment film 125′ may be attached to a rear surface of a semiconductor wafer 120′. The semiconductor wafer 120′ may include chip regions CR divided by a scribe region SL. The semiconductor wafer 120′ may include connection pads 121 disposed in the chip regions CR. The connection pads 121 may be disposed to be adjacent to at least one side of the chip regions CR. A preliminary passivation layer 122′, covering the chip regions CR, may be formed on a front surface of the semiconductor wafer 120′. The preliminary passivation layer 122′ may be formed using PSPI. The preliminary attachment film 125′ may be attached to a rear surface of the semiconductor wafer 120′ to which a backgrounding process is applied.

Before or after the preliminary attachment film 125′ is attached, trenches 122TR, extending to at least one edge of the chip regions CR while exposing the connection pads 121, may be formed. The trenches 122TR may be formed by removing at least a portion of the preliminary passivation layer 122′. The preliminary passivation layer 122′ may be patterned using a photolithography process.

Referring to FIG. 3B, a plurality of semiconductor chips 120 may be formed by cutting the semiconductor wafer 120′. The plurality of semiconductor chips 120 may correspond to the chip regions CR of the semiconductor wafer 120′. The plurality of semiconductor chips 120 may have a front surface on which a passivation layer 122 is disposed and a rear surface on which an attachment film 125 is disposed. The passivation layer 122 may be formed by the preliminary passivation layer 122′ cut together with the semiconductor wafer 120′. The attachment film 125 may be formed by a preliminary attachment film 125′ cut together with the semiconductor wafer 120′. A dummy pattern 123 may be exposed on at least one side surface SS′ and/or a front surface FS of the semiconductor chip 120.

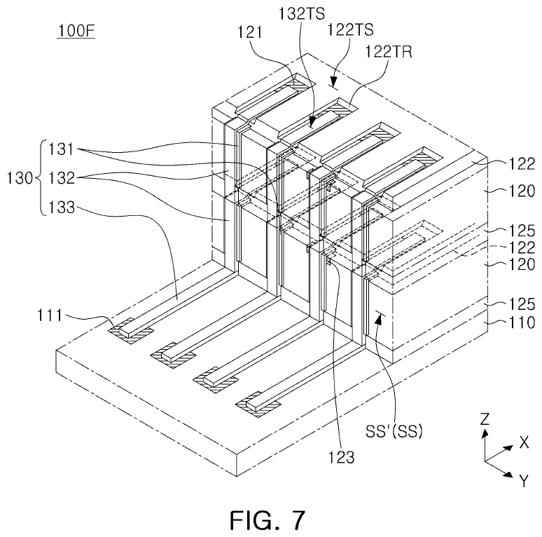

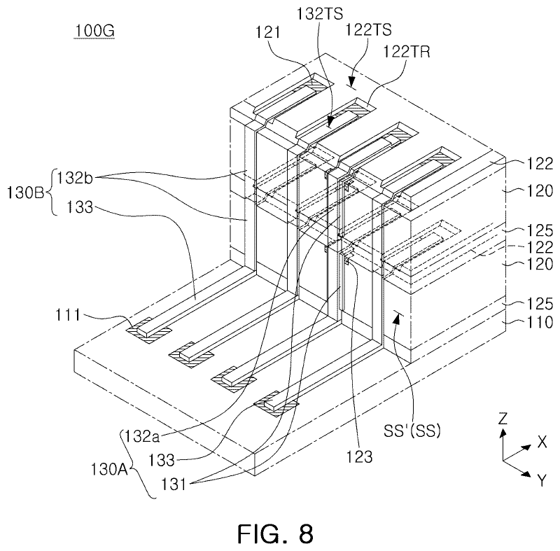

Referring to FIG. 3C, insulating patterns 131, covering at least one side surface SS′ of each of the plurality of semiconductor chips 120, may be formed. The insulating patterns 131 may be formed, for example, by coating and curing insulating ink including an epoxy-based resin. The insulating ink may be coated on one side surface SS′ of the semiconductor chip 120 using a dispenser or a printer. The insulating patterns 131 may be formed up to the one side surface SS′ of the semiconductor chip 120 along the trenches 122TR. In some example embodiments, the insulating patterns 131 may be formed only in a local region of each of the side surface SS′ and the front surface FS of the semiconductor chip 120, on which the conductive dummy pattern 123 is exposed (the example embodiment of FIG. 7), or may be selectively formed only in a region in which the conductive dummy pattern 123 is positioned (the example embodiment of FIG. 8). In an embodiment, each insulating pattern 131 may be disposed on the one side surface SS′ and a portion of the front surface FS exposed by a corresponding trench 122TR.

Referring to FIG. 3D, conductive patterns 132 may be formed. The conductive patterns 132 may extend onto the insulating patterns 131 from the connection pads 121 of each of the plurality of semiconductor chips 120. The conductive patterns 132 may extend up to the one side surface SS′ of the semiconductor chip 120 along the trenches 122TR. Ends of the conductive patterns 132 may correspond to lower ends of the attachment films 125, or may be spaced apart from each other by a predetermined distance. The conductive patterns 132 may be spaced apart from the conductive dummy pattern 123 by the insulating patterns 131. For example, the conductive patterns 132 may be formed by coating conductive ink including a metal such as aluminum (Al) and silver (Ag). The conductive ink may be coated in the form of a pattern designed through a dispensing process or a printing process. According to an example embodiment, the conductive patterns 132 may be cured in the present operation or in a subsequent operation (FIG. 3G).

Referring to FIG. 3E, bonding patterns 133 may be formed on a substrate 110. Although illustrated in the form of a unit substrate, the substrate 110 may be a strip substrate to which a plurality of substrates 110 are connected. The bonding patterns 133 may extend in at least one direction from the bonding pads 111. For example, the bonding patterns 133 may be formed by coating conductive ink including a metal such as aluminum (Al) and silver (Ag). The conductive ink may be coated in the form of a pattern designed through a dispensing process or a printing process. In some example embodiments, the bonding patterns 133 may be cured in the present operation or in a subsequent operation (FIG. 3G).

Referring to FIG. 3F, the plurality of semiconductor chips 120 may be attached to the substrate 110. The plurality of semiconductor chips 120 may be stacked such that one side surfaces SS′ thereof are aligned in a vertical direction. The plurality of semiconductor chips 120 may include conductive patterns 132 extending from the connection pads 121 to a lower end of at least one side surface SS′. The plurality of semiconductor chips 120 may be stacked such that ends of the conductive patterns 132 are electrically connected to one of the conductive patterns 132 or the bonding patterns 133, adjacent to each other in the vertical direction. The plurality of semiconductor chips 120 may be stacked in a greater number than that illustrated in the drawings. The conductive patterns 132 may be buried in one of the attachment films 125, adjacent to each other in the vertical direction. The trenches 122TR may prevent the conductive ink from spreading to the surroundings and causing a short circuit between the conductive patterns 132 prior to curing the conductive ink to form the conductive patterns 132.

Referring to FIG. 3G, after the plurality of semiconductor chips 120 are stacked, the bonding patterns 133 and the conductive patterns 132 may be cured. Thereafter, a molding layer 140 and connection bumps 115 may be formed, and then individual packages may be formed by performing a sawing process.

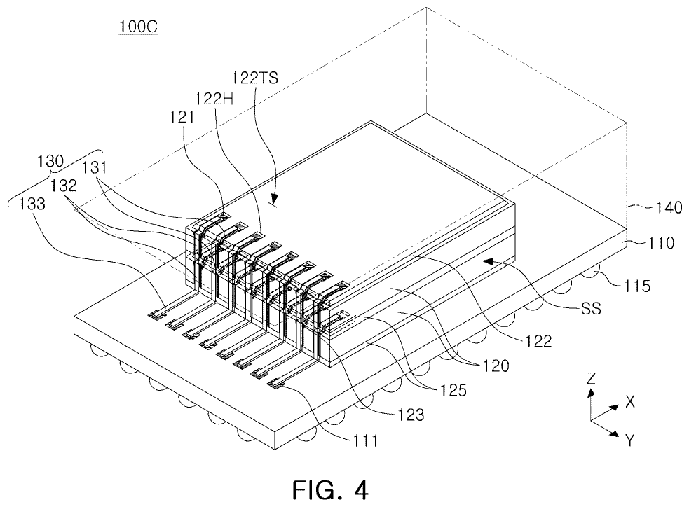

FIG. 4 is a partially enlarged view of a semiconductor package 100C according to an example embodiment.

Referring to FIG. 4, the semiconductor package 100C according to an example embodiment may have features the same as or similar to those described with reference to FIGS. 1A to 3G, except that conductive patterns 132 are disposed on an upper end surface 122TS of a passivation layer 122. The passivation layer 122 may have openings 122H exposing at least portions of the connection pads 121. The conductive patterns 132 may extend along the upper end surface 122TS of the passivation layer 122 and one side surface SS′ of a semiconductor chip 120. The conductive patterns 132 may be buried in one of attachment films 125, adjacent to each other in a vertical direction (Z-direction). An uppermost conductive pattern 132, among the conductive patterns 132, may be buried in a molding layer 140. The attachment film 125 and the molding layer 140 may fill a space between conductive patterns 132, adjacent to each other in a horizontal direction (for example, a Y-direction).

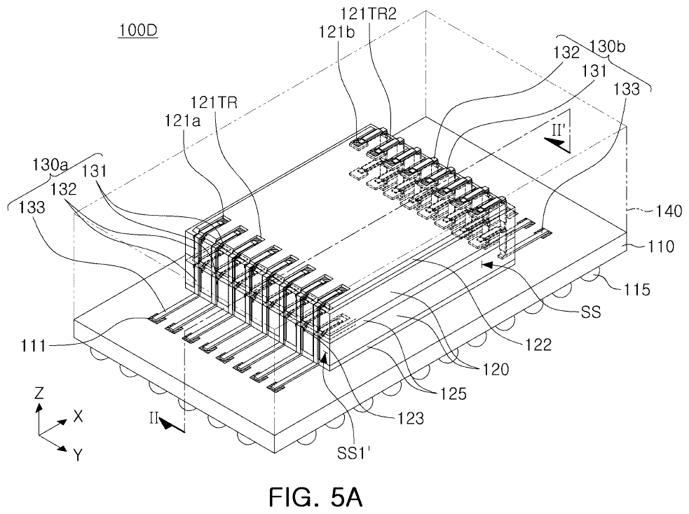

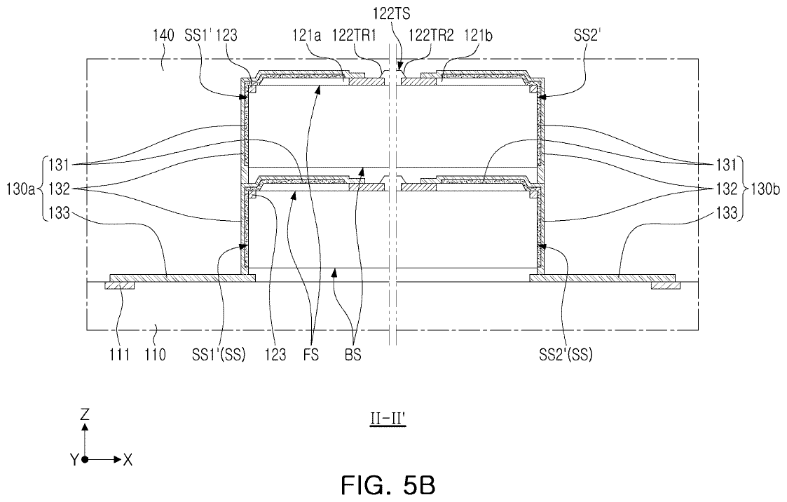

FIG. 5A is a perspective view of a semiconductor package 100D according to an example embodiment, and FIG. 5B is a cross-sectional view taken along line II-II′ of FIG. 5A.

Referring to FIGS. 5A and 5B, the semiconductor package 100D according to an example embodiment may have features the same as or similar to those described with reference to FIGS. 1A to 4, except that a plurality of connection members 130 are disposed on two or more side surfaces of a semiconductor chip 120. The plurality of connection members 130 may include connection members 130a and 130b disposed in different directions. For example, the plurality of connection members 130 may include first connection members 130a connecting first connection pads 121a to bonding pads 111, and second connection members 130b connecting second connection pads 121b to the bonding pads 111. The connection pads 121 of each of the plurality of semiconductor chips 120 may include first connection pads 121a adjacent to a first edge SS1′, and second connection pads 121b adjacent to a second edge SS2′. The passivation layer 122 may include first trenches 122TR1 exposing at least a portion of each of the first connection pads 121a, the first trenches 122TR1 extending to the first edge, and second trenches 122TR2 exposing at least a portion of each of the second connection pads 121b, the second trenches 122TR2 extending to the second edge. In some example embodiments, the plurality of connection members 130 may further include third connection members disposed on a third side surface of the semiconductor chip 120. In some example embodiments, the plurality of connection members 130 may further include fourth connection members disposed on a fourth side surface of the semiconductor chip 120.

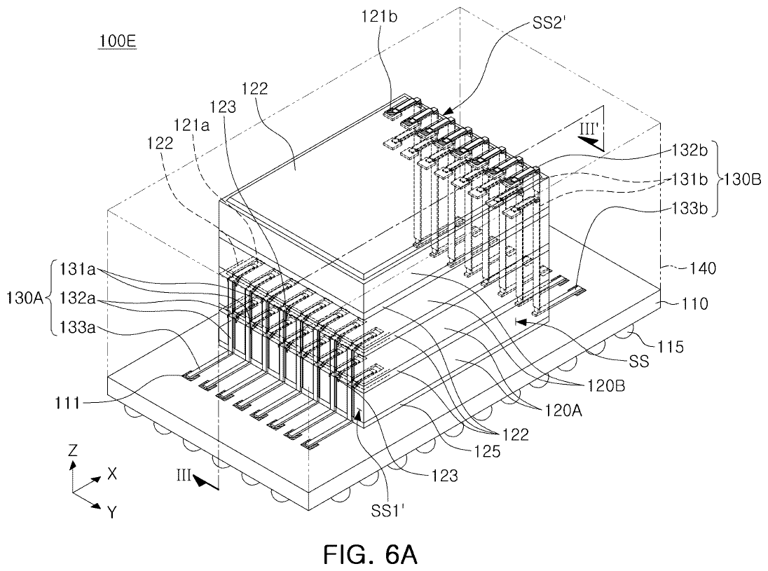

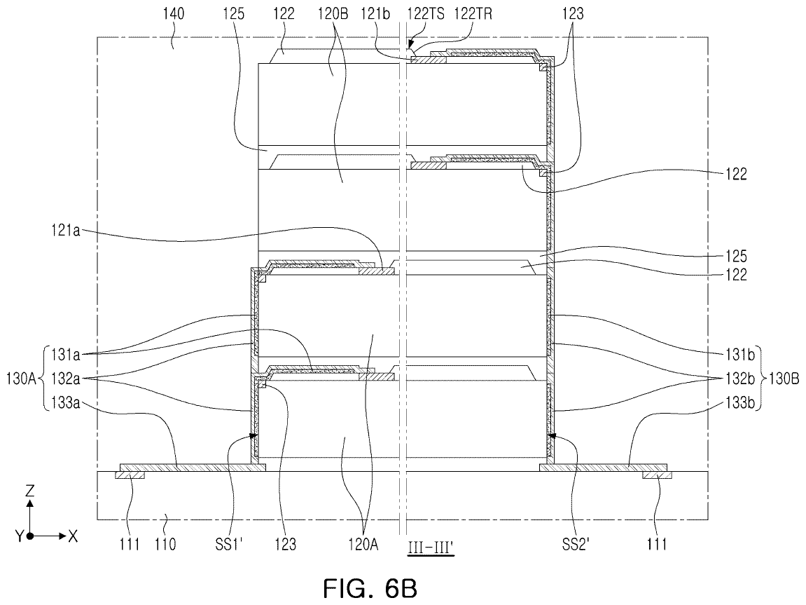

FIG. 6A is a perspective view of a semiconductor package 100E according to an example embodiment, and FIG. 6B is a cross-sectional view taken along line III-III′ of FIG. 6A.

Referring to FIGS. 6A and 6B, the semiconductor package 100E according to an example embodiment may have features the same as or similar to those described with reference to FIGS. 1A to 5B, except that a plurality of semiconductor chips 120 are connected to the bonding pads 111 in different directions. A plurality of semiconductor chips 120 may include a first group 120A including first connection pads 121a adjacent to the first edge SS1′, and a second group 120B disposed on the first group and including second connection pads 121b adjacent to the second edge SS2′.

The plurality of connection members 130 may include a first group 130A connecting the first connection pads 121a to the bonding pads 111, and a second group 130B connecting the second connection pads 121b to the bonding pads 111.

The first group of connection members 130A may include first insulating patterns 131a on a first side surface SS1′ of each of the first group of semiconductor chips 120a, first conductive patterns 132a extending from first connection pads 121a of each of the first group of the semiconductor chips 120A onto the first insulating patterns 131a, and a bonding pattern 133a extending from the bonding pads 111 to a lowermost conductive pattern, among the first conductive patterns 132a.

The second group of connection members 130B may include second insulating patterns 131b on a second side surface SS2′ of each of the first group and the second group of semiconductor chips 120A and 120B, second conductive patterns 132b extending from second connection pads 121b of each of the second group of the semiconductor chips 120B onto the second insulating patterns 131b, and a bonding pattern 133b extending from the bonding pads 111 to a lowermost conductive pattern, among the second conductive patterns 132b.

FIG. 7 is a partially enlarged view of a semiconductor package 100F according to an example embodiment.

Referring to FIG. 7, the semiconductor package 100F according to an example embodiment may have features the same as or similar to those described with reference to FIGS. 1A to 6B, except for a cover region of insulating patterns 131. The insulating patterns 131 may be formed only on a portion in which a conductive dummy pattern 123 is exposed. The conductive dummy pattern 123 may be a portion of a TEG pattern. For example, the insulating patterns 131 may be formed only on a portion of each of a side surface SS′ and a front surface FS of a semiconductor chip 120 to electrically and physically isolate the conductive dummy patterns 123 from each other. The conductive patterns 132 may extend onto the insulating patterns 131, covering the conductive dummy pattern 123.

FIG. 8 is a partially enlarged view of a semiconductor package 100G according to an example embodiment.

Referring to FIG. 8, the semiconductor package 100G according to an example embodiment may have features the same as or similar to those described with reference to FIGS. 1A to 7, except for a cover region of insulating patterns 131. The insulating patterns 131 may be selectively formed only on a portion in which a conductive dummy pattern 123 is exposed. For example, a plurality of connection members 130 may include a first group 130A and a second group 130B. Each of the first group of connection members 130A may include insulating patterns 131, first conductive patterns 132a, bonding patterns 133, and each of the second group of connection members 130B may include only second conductive patterns 132b and bonding patterns 133 extending from connection pads 121 of each of a plurality of semiconductor chips 120 to at least a region of a side surface SS′ that is free of the conductive dummy pattern 123.

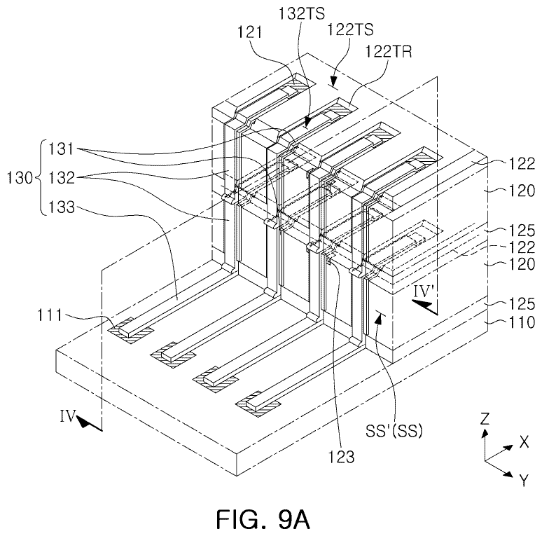

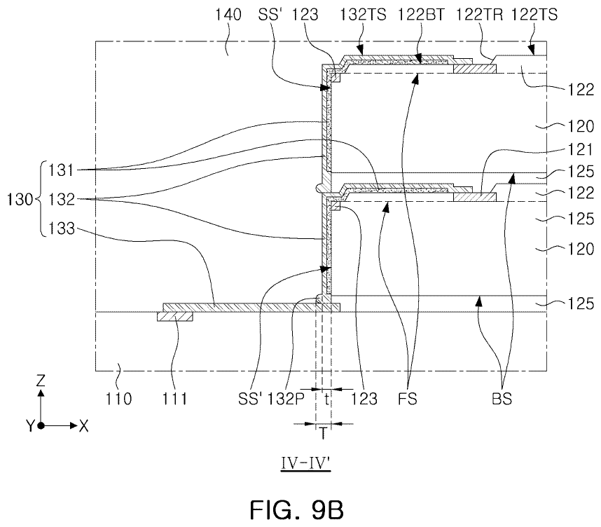

FIG. 9A is a partially enlarged view of a semiconductor package 100H according to an example embodiment, and FIG. 9B is a cross-sectional view taken along line IV-IV′ of FIG. 9A.

Referring to FIGS. 9A and 9B, the semiconductor package 100H according to an example embodiment may have features the same as or similar to those described with reference to FIGS. 1A to 8, except for a form of a connection portion between conductive patterns 132. Ends of the conductive patterns 132 may be pressed against the conductive patterns 132, adjacent to each other in a vertical direction (Z-direction), or bonding patterns 133 in a process of stacking semiconductor chips 120, thereby protruding in at least one direction. For example, the conductive patterns 132 may include protrusions 132P, respectively adjacent to the ends. The protrusions 132P of the conductive patterns 132 may have a thickness T greater than a thickness t of each of the conductive patterns 132 in a direction, perpendicular to one side surface SS′ of the semiconductor chip 120.

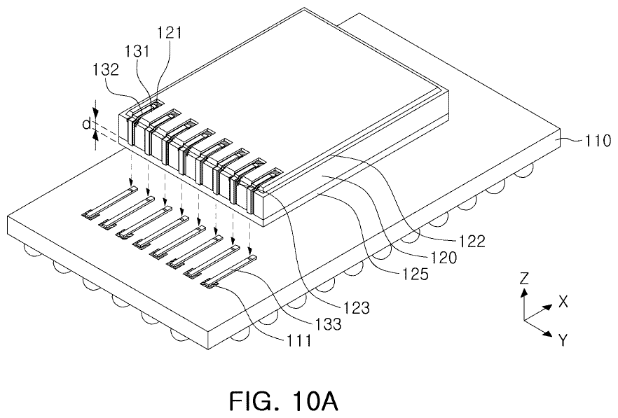

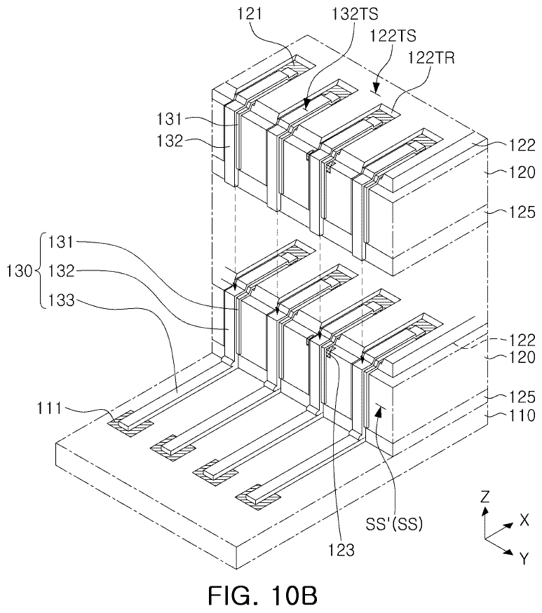

FIGS. 10A and 10B are diagrams illustrating a process of manufacturing the semiconductor package 100H of FIG. 9A.

Referring to FIG. 10A, conductive patterns 132 may extend up to a lower end of an attachment film 125 along one side surface SS′ of a semiconductor chip 120. Ends of the conductive patterns 132 may be spaced apart from the lower end of the attachment film 125 by a predetermined distance d. The distance d between the lower end of the attachment film 125 and the ends of the conductive patterns 132 may be less than a thickness of the conductive pattern 132 or the bonding pattern 133, which will contact the ends of the conductive patterns 132 in a subsequent process. The conductive patterns 132 may be formed of conductive ink coated using a dispenser or a printer. Semiconductor chips 120 may be stacked in a state in which the conductive patterns 132 are not cured.

Referring to FIG. 10B, a plurality of semiconductor chips 120 may be attached to a substrate 110. The plurality of semiconductor chips 120 may be stacked such that ends of the conductive patterns 132 are aligned in a vertical direction. The ends of the conductive patterns 132 may be pressed against the conductive patterns 132 or bonding patterns 133, adjacent to each other in the vertical direction (Z-direction), in a process of stacking the semiconductor chips 120, thereby protruding in one direction. Thereafter, the conductive patterns 132 and the bonding patterns 133 may be cured.

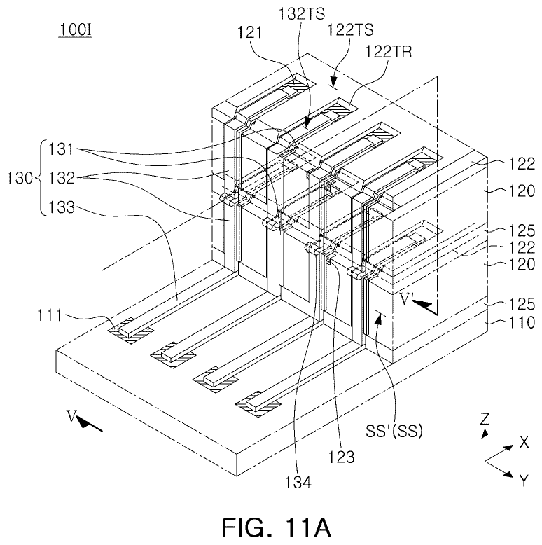

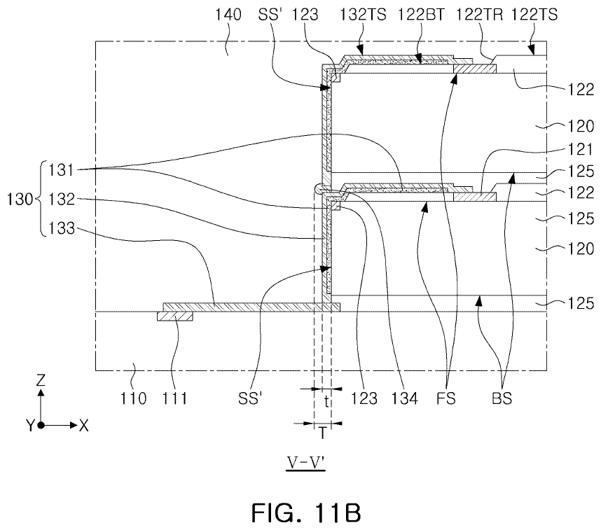

FIG. 11A is a partially enlarged view of a semiconductor package 100I according to an example embodiment, and FIG. 11B is a cross-sectional view taken along line V-V′ of FIG. 11A.

Referring to FIGS. 11A and 11B, the semiconductor package 100I according to an embodiment may have features the same as or similar to those described with reference to FIGS. 1A to 8, except for a form of a connection portion between conductive patterns 132. A plurality of connection members 130 may further include connection patterns 134. The connection patterns 134 may be disposed between an end of each conductive pattern 132 and one of the conductive patterns 132 and/or between the end of each conductive pattern 132 and a bonding pattern 133. The connection patterns 134 may be formed by coating conductive ink including a metal such as aluminum (Al) and silver (Ag). The connection patterns 134 may have a thickness T greater than a thickness t of each of the conductive patterns 132 in a direction, perpendicular to one side surface SS′.

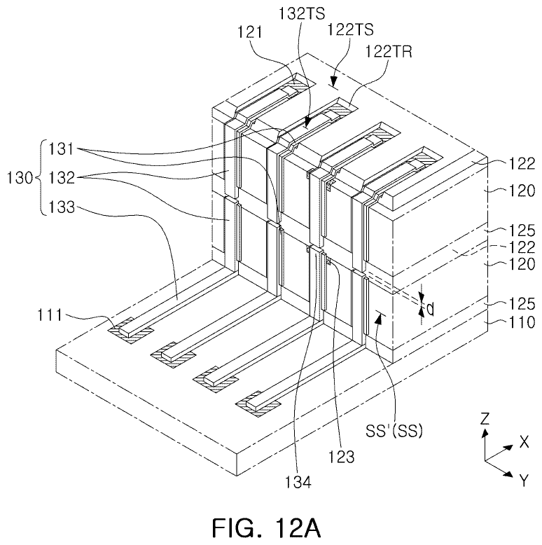

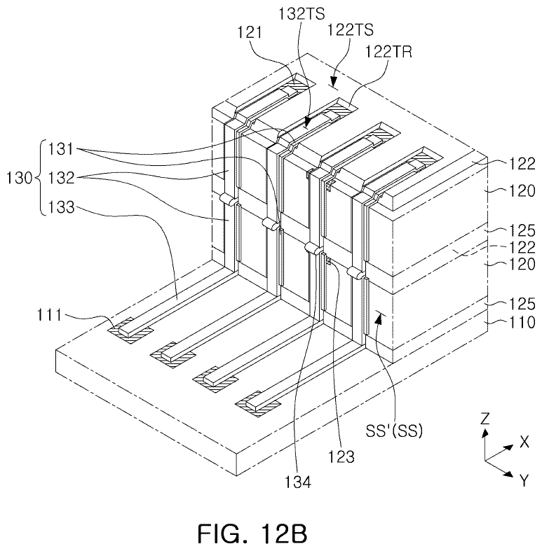

FIGS. 12A and 12B are diagrams illustrating a manufacturing process of the semiconductor package 100I of FIG. 11A.

Referring to FIG. 12A, ends of conductive patterns 132 may be spaced apart from a lower end of the attachment film 125 by a predetermined distance d. The distance d between the lower end of the attachment film 125 and the ends of the conductive patterns 132 may be greater than a thickness of the conductive pattern 132 or a bonding pattern 133, which will contact the ends of the conductive patterns 132 in a subsequent process. The conductive patterns 132 may be formed of conductive ink applied using a dispenser or a printer. The semiconductor chips 120 may be stacked in a state in which the conductive patterns 132 are not cured. A plurality of semiconductor chips 120 may be attached to a substrate 110. The plurality of semiconductor chips 120 may be stacked such that the ends of the conductive patterns 132 are aligned in a vertical direction (Z-direction). The ends of the conductive patterns 132 may be spaced apart from the conductive patterns 132 or the bonding patterns 133, adjacent to each other in the vertical direction (Z-direction).

Referring to FIG. 12B, before the conductive patterns 132 and the bonding patterns 133 are cured, connection patterns 134 may be formed between an end of each of the conductive patterns 132 and one of the conductive patterns 132 or between an end of each of the conductive patterns 132 and the bonding patterns 133. The connection patterns 134 may be formed by coating conductive ink between the conductive patterns 132 and the end of each of the conductive patterns 132, or between the bonding pattern 133 and the end of each of the conductive patterns 132. Thereafter, the connection patterns 134, the conductive patterns 132, and the bonding patterns 133 may be cured.

According to example embodiments of the present inventive concept, connection members on side surfaces of a plurality of semiconductor chips may be applied, thereby providing a semiconductor package having a reduced size and high performance, and a method of manufacturing the same.

While example embodiments have been shown and described above, it will be apparent to those skilled in the art that modifications and variations could be made without departing from the scope of the present disclosure as defined by the appended claims.

What is claimed is:

1. A semiconductor package comprising:
a substrate including a plurality of bonding pads;
a plurality of first semiconductor chips stacked on the substrate in a vertical direction perpendicular to an upper surface of the substrate, wherein each first semiconductor chip of the plurality of first semiconductor chips has a first rear surface facing the substrate, a first front surface opposite to the first rear surface, and a plurality of side surfaces connecting the first front surface to the first rear surface;
a plurality of first connection members electrically connects a corresponding first bonding pad of the plurality of bonding pads to each first semiconductor chip of the plurality of first semiconductor chips; and
a plurality of connection bumps disposed below the substrate and electrically connected to the plurality of bonding pads,
wherein each first semiconductor chip of the plurality of first semiconductor chips includes:
a plurality of first connection pads adjacent to a first edge of the first front surface; and
a passivation layer disposed on the first front surface and having a plurality of first trenches extending from the first edge of the first front surface toward the plurality of first connection pads, each first trench of the plurality of first trenches exposing at least a portion of a corresponding first connection pad of the plurality of first connection pads,
wherein each first connection member of the plurality of first connection members includes:
a plurality of first insulating patterns disposed on a first side surface of a corresponding first semiconductor chip of the plurality of first semiconductor chips, the first side surface is connected to the first edge of the first front surface;
a first bonding pattern extending from a corresponding first bonding pad of the plurality of bonding pads toward a lowermost first semiconductor chip among the plurality of first semiconductor chips in a horizontal direction parallel to the upper surface of the substrate;
a first conductive pattern having a first end connected to the first bonding pattern and a second end disposed in a corresponding first trench of the plurality of first trenches.

2. The semiconductor package of claim 1,
wherein the first conductive pattern includes:
a vertical portion extending along the first side surface of the corresponding first semiconductor chip; and
a plurality of horizontal portions extending from the vertical portion to a corresponding connection pad of the plurality of first connection pads.

3. The semiconductor package of claim 2,
wherein each horizontal portion of the plurality of horizontal portions has the second end.

4. The semiconductor package of claim 2,
wherein the plurality of horizontal portions have a thickness in the vertical direction, and
wherein the plurality of first trenches has a depth in the vertical direction greater than the thickness of the plurality of horizontal portions.

5. The semiconductor package of claim 2,
wherein, in each first semiconductor chip, an upper surface of the passivation layer is positioned at the same level as or higher than an upper surface of a corresponding horizontal portion of the plurality of horizontal portions.

6. The semiconductor package of claim 2,
wherein, in each first semiconductor chip, the passivation layer overlaps a corresponding horizontal portion of the plurality of horizontal portions in the horizontal direction.

7. The semiconductor package of claim 2,
wherein the vertical portion include a plurality of vertical sections, with two adjacent vertical sections of the plurality of vertical sections being connected in the vertical direction, and
wherein each vertical section of the plurality of vertical sections includes:
an uppermost end contacting a corresponding horizontal portion of the plurality of horizontal portions, and
a lowermost end having a protrusion protruding in a direction away from the first side surface.

8. The semiconductor package of claim 2,
wherein the vertical portion include a plurality of vertical sections and a plurality of connection patterns, and
wherein each connection pattern is disposed in a space between corresponding two adjacent vertical sections of the plurality of vertical sections.

9. The semiconductor package of claim 8,
wherein the plurality of connection patterns have a thickness greater than a thickness of each vertical section of the plurality of vertical sections in a direction perpendicular to the first side surface.

10. The semiconductor package of claim 2,
wherein each first insulating pattern of the plurality of first insulating patterns is further disposed in a space between a corresponding horizontal portion of the plurality of horizontal portions and a first front surface of the corresponding first semiconductor chip.

11. The semiconductor package of claim 1, further comprising:
a plurality of attachment films including a lowermost attachment film between the substrate and a lowermost first semiconductor chip of the plurality of first semiconductor chips and an intervening attachment film between two adjacent first semiconductor chips, in the vertical direction, among the plurality of first semiconductor chips,
wherein the intervening attachment film fills a corresponding first trench of the lowermost first semiconductor chip.

12. The semiconductor package of claim 1,
wherein a width, in a horizontal direction parallel to the first edge, of each first trench of the plurality of first trenches is greater than a width of a corresponding first connection pad of the plurality of first connection pads.

13. The semiconductor package of claim 1, further comprising: a plurality of second connection members disposed on the substrate and the plurality of first semiconductor chips,
wherein each second connection member of the plurality of second connection members electrically connects a corresponding second bonding pad of the plurality of bonding pads to each first semiconductor chip of the plurality of first semiconductor chips, and
wherein each first semiconductor chip of the plurality of first semiconductor chips further includes:
a plurality of second connection pads adjacent to a second edge, opposite to the first edge, of the first front surface; and
a plurality of second trenches extending from the second edge of the first front surface toward the plurality of second connection pads, wherein each second trench of the plurality of second trenches exposes at least a portion of a corresponding second connection pad of the plurality of second connection pads.

14. The semiconductor package of claim 1, further comprising:
a plurality of second semiconductor chips stacked on the plurality of first semiconductor chips in the vertical direction,
wherein each second semiconductor chip of the plurality of second semiconductor chips includes a second front surface and a plurality of second connection pads adjacent to a second edge of the second front surface, and
wherein, when viewed in a plan view, the first edge of the first front surface and the second edge of the second front surface are opposite to each other; and
a plurality of second connection members disposed on the substrate, the plurality of first semiconductor chips, and the plurality of second semiconductor chips, wherein each second connection member of the plurality of second connection members electrically connects a corresponding second bonding pad of the plurality of bonding pads to each second semiconductor chip of the plurality of second semiconductor chips.

15. The semiconductor package of claim 14,
wherein each second semiconductor chip of the plurality of second semiconductor chips includes:
a plurality of second connection pads adjacent to the second edge of the second front surface;
a second passivation layer disposed on the second front surface and having a plurality of second trenches extending from the second edge of the second front surface toward the plurality of second connection pads, wherein each second trench of the plurality of second trenches exposes at least a portion of a corresponding second connection pad of the plurality of second connection pads,
wherein each second connection member of the plurality of second connection members includes:
a plurality of second insulating patterns disposed on a second side surface of a corresponding second semiconductor chip of the plurality of second semiconductor chips, the second side surface is connected to the second edge of the second front surface;
a second bonding pattern extending from a corresponding second bonding pad of the plurality of bonding pads toward the lowermost first semiconductor chip in the horizontal direction; and
a second conductive pattern having a first end connected to the second bonding pattern and a second end disposed in a corresponding second trench of the plurality of second trenches.

16. A semiconductor package comprising:
a substrate including a plurality of bonding pads;
a plurality of semiconductor chips stacked on the substrate in a vertical direction perpendicular to an upper surface of the substrate, each semiconductor chip of the plurality of semiconductor chips having a rear surface facing the substrate, a front surface opposite to the rear surface, and a plurality of side surfaces connecting the front surface to the rear surface;
a plurality of attachment films, each attachment film being disposed on a rear surface of a corresponding semiconductor chip of the plurality of semiconductor chips; and
a plurality of connection members electrically connecting the plurality of semiconductor chips and the plurality of bonding pads of the substrate with each other;
wherein each of the plurality of semiconductor chips includes:
a plurality of connection pads adjacent to a first edge of the front surface; and
a passivation layer disposed on the front surface, the passivation layer exposing at least a portion of each connection pad of the plurality of connection pads, and
wherein each connection member of at least some connection members, among the plurality of connection members, includes:
a plurality of insulating patterns on one side surface, among the plurality of side surfaces of each of the plurality of semiconductor chips, that is connected to the first edge; and
a plurality of conductive patterns extending from the plurality of connection pads of each semiconductor chip of the plurality of semiconductor chips onto the plurality of insulating patterns, the plurality of conductive patterns electrically connected to the plurality of bonding pads.

17. The semiconductor package of claim 16,
wherein the plurality of conductive patterns are buried in a corresponding attachment film of the plurality of attachment films.

18. The semiconductor package of claim 16, further comprising:
a molding layer covering the plurality of semiconductor chips,
wherein an uppermost conductive pattern, among the plurality of conductive patterns, is buried in the molding layer.

19. A semiconductor package comprising:
a substrate including a plurality of bonding pads;
a plurality of semiconductor chips stacked on the substrate in a vertical direction perpendicular to an upper surface of the substrate, each semiconductor chip of the plurality of semiconductor chips having a rear surface facing the substrate, a front surface opposite to the rear surface, and a plurality of side surfaces connecting the front surface to the rear surface; and
a plurality of connection members electrically connecting the plurality of semiconductor chips and the plurality of bonding pads of the substrate with each other;
wherein each semiconductor chip of the plurality of semiconductor chips includes:
a plurality of connection pads adjacent to a first edge of the front surface;
a passivation layer disposed on the front surface, the passivation layer exposing at least a portion of each connection pad of the plurality of connection pads; and
a conductive dummy pattern disposed at the front surface and a first side surface among the plurality of side surfaces, the first side surface being connected to the first edge of the front surface, and
wherein the plurality of connection members include a first group of connection members, each connection member of the first group of connection members including:
an insulating pattern covering the conductive dummy pattern on the first side surface and the front surface of a corresponding semiconductor chip of the plurality of semiconductor chips; and
a conductive pattern extending from a corresponding connection pad of each semiconductor chip of the plurality of semiconductor chips onto the insulating pattern, the conductive pattern electrically connected to a corresponding one of the plurality of bonding pads.

20. The semiconductor package of claim 19,
wherein the plurality of connection members further includes a second group of connection members, and
wherein each connection member of the second group of connection members includes a conductive pattern extending from a corresponding connection pad of the plurality of semiconductor chips onto at least a region of the first side surface that is free of the conductive dummy pattern.
